(19) United States
(12) Patent Application Publication
(10) Pub. No.: US 2013/0099277 A1
(43) Pub. Date: Apr. 25, 2013

(54) SELECTIVE DRY ETCHING OF N-FACE (Al,In,Ga)N HETEROSTRUCTURES

(71) Applicant: The Regents of the University of California, Oakland, CA (US)

(72) Inventors: James S. Speck, Goleta, CA (US); Evelyn L. Hu, Cambridge, MA (US); Claude C.A. Weisbuch, Paris (FR); Yong Seok Choi, Goleta, CA (US); Gregor Koblmuller, Santa Barbara, CA (US); Michael Iza, Goleta, CA (US); Christophe Hurni, Goleta, CA (US)

(73) Assignee: THE REGENTS OF THE UNIVERSITY OF CALIFORNIA, Oakland, CA (US)

(21) Appl. No.: 13/660,782

(22) Filed: Oct. 25, 2012

Related U.S. Application Data
(60) Provisional application No. 61/551,181, filed on Oct. 25, 2011.

(51) Int. Cl. H01L 33/02; H01L 21/306; H01L 29/20

(52) U.S. Cl. 257/101; 438/37; 257/615; 438/706; 257/E33.023; 257/E29.089; 257/E21.222

(57) ABSTRACT

A method of selective dry etching of N-face (Al,In,Ga)N heterostructures through the incorporation of an etch-stop layer into the structure, and a controlled, highly selective, etch process. Specifically, the method includes: (1) the incorporation of an easily formed, compatible etch-stop layer in the growth of the device structure, (2) the use of a laser-lift off or similar process to decouple the active layer from the original growth substrate, and (3) the achievement of etch selectivity higher than 14:1 on N-face (Al,In,Ga)N.

### CROSS-REFERENCE TO RELATED APPLICATION

This application claims the benefit under 35 U.S.C. §119(e) of U.S. Provisional Patent Application No. 61/551,181, filed on Oct. 25, 2011, by James S. Speck, Evelyn L. Hu, Claude C. A. Weisbuch, Yong Seok Choi, Gregor Koblmuller, Michael Iza, and Christophe Hurni, and entitled “SELECTIVE DRY ETCHING OF N-FACE (Al,In,Ga)N HETEROSTRUCTURES,” attorneys' docket number 30794.413-US-P1 (2007-460-1), which application is hereby incorporated by reference herein.

### STATEMENT REGARDING FEDERALLY SPONSORED RESEARCH AND DEVELOPMENT

This invention was made with Government support under Grant No. DE-FC26-06NT42857 awarded by the U.S. Department of Energy. The Government has certain rights in this invention.

### BACKGROUND OF THE INVENTION

1. Field of the Invention

The invention is related generally to the field of electronic and optoelectronic devices, and more particularly, to selective dry etching of nitrogen face (N-face) (Al,In,Ga)N heterostructures.

2. Description of the Related Art

(Note: This application references a number of different publications as indicated throughout the specification by one or more reference numbers within brackets, e.g., [Ref. X]. A list of these different publications ordered according to these reference numbers can be found below in the section entitled “References.” Each of these publications is incorporated by reference herein.)

Typical GaN-based light-emitting diodes (LEDs) are planar structures, where a several-micron-thick GaN template and InGaN/GaN quantum-well active region are grown on a lower index Sapphire substrate. The top air/GaN interface and the GaN/Sapphire interface serve as mirrors to form discrete bound states for photons, so called guided modes. As these guided modes propagate parallel to the planar geometry, the direct emission in the vertical direction is low, i.e., a few percent of the total emission. Therefore, the integration (packaging) of external optics is necessary to retain the vertical emission.

Submicron-thick micro-cavity light emitting diodes (MCLEDs) [Ref 1] and photonic-crystal-MCLEDs (PC-MCLEDs) [Ref 2] promise superior performance to conventional LEDs. Tailoring of the modal characteristics can lead to enhancement of spontaneous emission [Ref 3], spectral purity [Ref 4], and directionality [Refs. 5-6], which contribute to increased brightness and energy efficiency. This invention addresses critical challenges in the fabrication of such devices, enabling commercial realization of these LEDs with exceptional extraction efficiency.

In more conventional III-V materials, such as GaAs and InP, highly efficient microcavity optical devices with controlled light emission can be formed through the monolithic growth of high reflectivity mirrors, and a thin active region whose thickness and composition are controlled by the precision of the epitaxial growth technique. Such techniques are not practical, or easily implemented or accomplished, in GaN-based LEDs and lasers.

For GaN-based LEDs and lasers, a high quality underlying mirror is required to direct light away from the substrates, which serves as a loss channel for the generated light. Although AlGaN/GaN Distributed Bragg Reflectors (DBRs) have been formed, the low index contrast between AlGaN/GaN requires high Al composition and a large number of DBR periods for a highly reflective mirror [Ref 7]. The inherent strain in this heterostructure leads to the formation of cracks and other defects in the mirror structure [Ref. 8].

The lossy effects of the substrate may be addressed through removal of the active layer from the substrate, through techniques like laser lift-off (LLO) [Refs. 9-10]. The lift-off structure can then be bonded to a different substrate, and appropriate dielectric DBRs deposited [Ref 11]. However, a certain minimum thickness (several microns) between the active area and the original substrate is required to ensure the integrity of the active region during the lift-off process. Precision control of the post LLO etch in the vertical direction determines the thickness of the MCLED; uniformity of the etch in the lateral direction will ensure a high yield of devices. Such etch control is a critical factor in the fabrication and ultimate manufacturability of such devices.

Recently, T. Fujii et al. [Ref 1] have demonstrated submicron-thick MCLEDs by utilizing the LLO technique and the nonselective thinning process, i.e., reactive ion etching (RIE) and successive chemical mechanical polishing (CMP) [Ref. 12]. This processing scheme has further been a basis for exploring PC-MCLEDs [Ref 2]. However, the adopted thinning method lacks reproducibility, precision, and scalability in controlling the microcavity thickness.

The present invention proposes the incorporation of an etch-stop layer into the device structure, and a controlled, highly selective, etch process. Specifically, the present invention includes: (1) the incorporation of an easily formed, compatible etch-stop layer in the growth of the device structure, (2) the use of a laser-lift off or similar process to decouple the active layer from the original ‘growth’ substrate, and (3) the achievement of etch selectivity higher than 14:1 on N-face (Al,In,Ga)N.

For a GaN structure, InₓGa₁₋ₓN or AlₓGa_{1-y}N layers can be epitaxially incorporated, generally with a thickness commensurate with a critical thickness [Ref. 13]. Generally, it is expected that the higher the chemical difference between etch stop layer and the surrounding material, the higher the achievable dry-etch or wet-etch selectivity.

The choices of selective wet etches are limited, although some high-temperature etches have been found for AlGaN and photoelectrochemical etching has been shown to be effective for a broad composition of (Al,Ga,In)N. There are a number of dry or gas-phase etches; in general, all such processes, e.g., RIE, inductively coupled plasma (ICP) etching, etc., contain a chemical component and an ion-assisted (physical) component.

Etch selectivities for the Group-III face (III-face) III-nitride materials have been demonstrated by, e.g., S. A. Smith et al. [Ref 14] using an ICP process with Cl₂ and Ar to etch GaN, AlGaN, and AlN. S. J. Pearton et al. [Ref 15] have utilized etch gases of Cl₂, BCl₃, SF₆, and Ar for ICP etching of GaN, AlN, and InN. The maximum etch selectivity of 6:1 was obtained for GaN:AlN by the Cl₂-based ICP.

The demonstration of selective etches for the III-face does not guarantee etch behavior of the N-face; differences in etch behavior of the two faces have already been suggested in Refs. 16-18. In fact, I. Waki et al. [Ref 19] have investigated the ICP etching of (0001) (-c) N-face GaN, which was obtained by LLO process. The etch rate of ˜7 nm/min was obtained with the flow rates of 20 sccm for BCl₃ and 5 sccm for SF₆, the chamber pressure of 4 Pa, and the source and bias powers of 250 W and 175 W, respectively. However, the etch selectivity was not achieved.

Thus, there is a need in the art for improved methods for nano-precision etching of GaN, AlGaN, InGaN, and AlInGaN, in the fabrication of electronic and optoelectronic devices. The present invention satisfies this need. Specifically, the present invention provides for selective dry etching of N-face (Al,In,Ga)N heterostructures.

### SUMMARY OF THE INVENTION

To overcome the limitations in the prior art described above, and to overcome other limitations that will become apparent upon reading and understanding the present specification, the present invention discloses a method for selective dry etching of N-face (Al,In,Ga)N heterostructures through the incorporation of an etch-stop layer into the structure, and a controlled, highly selective, etch process. Specifically, the present invention includes: (1) the incorporation of an easily formed, compatible etch-stop layer in the growth of the device structure, (2) the use of a laser-lift off or similar process to decouple the active layer from the original growth substrate, and (3) the achievement of etch selectivity higher than 14:1 on N-face (Al,In,Ga)N. The present invention also encompasses devices fabricated according to this method.

### BRIEF DESCRIPTION OF THE DRAWINGS

Referring now to the drawings in which like reference numbers represent corresponding parts throughout:

FIG. 1(a) are simplified schematic diagrams showing the steps of a method of the present invention, used for a conventional GaN-based LED grown on a Sapphire substrate, including laser debonding of the Sapphire substrate, followed by selective etching of a GaN template utilizing an etch stop layer.

FIG. 1(b) is a Scanning Electron Micrograph (SEM) of a test material with the Al_{0.30}Ga_{0.70}N etch stop layer grown by Molecular Beam Epitaxy (MBE).

FIGS. 2(a)-2(d) are simplified schematic diagrams showing the steps of a method of the present invention, used to verify the selective removal of N-face GaN by BCl₃ and SF₆ based ICP etching.

FIG. 3 is a SEM image of the etch surface after the 15 min ICP etching.

FIGS. 4(a) and 4(b) are SEM images taken after (FIG. 4(a)) the 20 min and (FIG. 4(b)) the additional 20 min (total 40 min) ICP etching; processes, wherein the initial 20 min ICP etching stopped at the Al_{0.30}Ga_{0.70}N etch stop layer, which could withstand the additional 20 min ICP process at the same condition.

FIGS. 5(a)-5(d) are SEM images showing the correlation between the micro-cone density and the Al composition (x) in the AlₓGa₁₋ₓN layer, wherein FIG. 5(a) shows x=0.15; FIG. 5(b) shows x=0.15; FIG. 5(c) shows x=0.30; and FIG. 5(d) shows x=0.51; and wherein the samples were processed at the same ICP condition concurrently.

FIGS. 6(a)-6(h) are simplified schematic diagrams showing the steps of a process, according to one embodiment of the present invention, used to fabricate MCLEDs and/or PC-MCLEDs for an epi-structure grown on a Sapphire substrate.

FIGS. 7(a)-7(i) are simplified schematic diagrams showing the steps of a process, according to one embodiment of the present invention, used to fabricate MCLEDs and/or PC-MCLEDs for an epi-structure grown on a free-standing GaN substrate.

FIG. 8 are simplified schematic diagrams showing the steps of a process, according to one embodiment of the present invention, used to fabricate a thin Group-III nitride-based film for efficient thermal management with a passive temperature control unit (heat dissipater) or an active temperature control unit (thermoelectric temperature controller).

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

This invention describes a method to utilize controllable and extremely high etch selectivities of (Al,In,Ga)N heterostructures for devices of those materials requiring fabrication with nano-scale precision. Specifically, this invention relates to a nano-precision etching method with reproducibility and scalability for GaN and its ternary and quaternary compounds incorporating aluminum and indium (AlGaN, InGaN, AlInGaN), which are essential for visible and ultraviolet optoelectronic devices and high-power electronic devices.

In one embodiment, the present invention discloses a method for dry etch selectivity in fabricating an opto-electronic device, by etching one or more nitride layers having an (Al,In,Ga)N etch-stop layer containing at least some Aluminum (Al), wherein the nitride layers and etch-stop layer comprise layers of dissimilar (Al,Ga,In)N composition and the nitride layers are etched at a higher rate than the etch-stop layer.

Other aspects of this embodiment include:
The nitride layers and etch-stop layer comprise layers having varying or graded compositions.
The etching is performed on an etch surface that is a (0001) (-c) Nitrogen-face (N-face) of the nitride layers, wherein the nitride layers comprise c-plane GaN layers and the etch surface is an as-grown (0001) (-c) N-face of the c-plane GaN layers.
The etch-stop layer comprises an AlₓGa₁₋ₓN layer with x>0, and more preferably, 0.1<x<0.5.
The etch-stop layer has a thickness that is greater than 1 nm, and more preferably, a thickness that is between 10 nm and 100 nm.
The nitride layers are etched by ICP etching using etch gases of SF₆, BCl₃, Cl₂, Ar, or O₂ at a source power P_{S} and bias power P_{B}, where 0<P_{S}<200 W, 0<P_{B}<100 W and P_{B}<P_{S}.
The ICP etching is carried out along with an initial chemical mechanical polishing or RIE using etch gases of SF₆, BCl₃, Cl₂, Ar, or O₂.

In another embodiment, the present invention discloses a method for dry etch selectivity in fabricating an opto-electronic device, by etching one or more nitride layers having an (Al,In,Ga)N etch-stop layer containing at least some Indium (In), wherein the nitride layers and etch-stop layer comprise layers of dissimilar (Al,Ga,In)N composition and the nitride layers are etched at a higher rate than the etch-stop layer.

Other aspects of this embodiment include:
The etch-stop layer is used as an etch stop over a Gallium face (Ga-face) or a Nitrogen face (N-face) of the nitride layers.
An etch product InCl₃ provides a dry etch selectivity for a chlorine-based etch gas.
An etch product InF₃ provides a dry etch selectivity for a fluorine-based etch gas.

### TECHNICAL DESCRIPTION

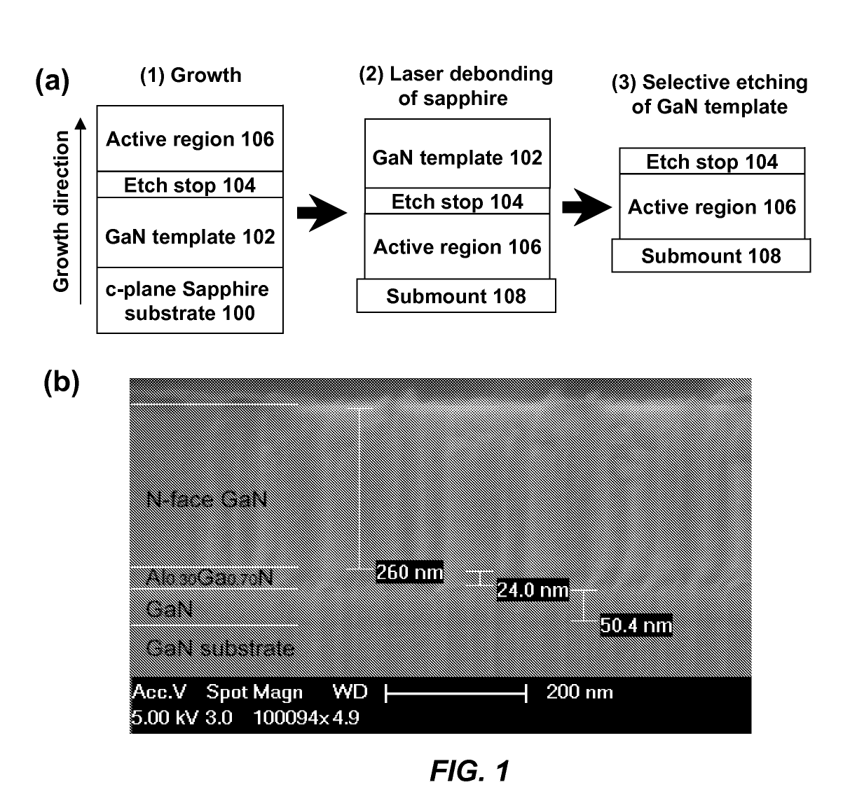

A particular embodiment of the present invention involves the formation of an AlGaN etch-stop layer. The device fabrication process and the role of the etch-stop layer are shown in FIG. 1(a), which shows a sequence of steps comprising: (1) growth of a conventional GaN-based LED on a c-plane Sapphire substrate 100 including a GaN template 102, an etch stop layer 104 and an active region 106; (2) laser debonding of the Sapphire substrate 100 and bonding of a submount 108; and (3) selective etching of the GaN template 102 utilizing the etch stop layer 104. The etch gas used must (1) etch GaN at a fairly substantial rate, (2) much higher than the rate of etching of the AlGaN. A choice of etch gas is a fluorine-containing gas, wherein Al is known to form the nonvolatile AlF₃ layer during fluorine-based dry etching, and another choice of etch gas is a chlorine-containing gas, wherein Al is known to form the nonvolatile AlCl₃ layer during chlorine-based dry etching. This knowledge is specifically developed further for the selective etching of (Al,In,Ga)N heterostructures, to achieve a minimal (˜0) etch rate of the AlGaN, with a measurable etch rate for GaN.

An alternative embodiment of the present invention involves the formation of an InGaN etch-stop layer in a similar structure and using a similar process to perform selective etching of the GaN template utilizing the etch stop layer. In this embodiment, the etch gas used must (1) etch GaN at a fairly substantial rate, (2) much higher than the rate of etching of the InGaN. Similar to Al, the choice of etch gas is a fluorine-containing gas, wherein In is known to form the nonvolatile InF₃ layer during fluorine-based dry etching, and another choice of etch gas is a chlorine-containing gas, wherein In is known to form the nonvolatile InCl₃ layer during chlorine-based dry etching.

The inventors have specifically investigated the etch selectivity between N-face GaN and an AlₓGa₁₋ₓN etch stop layer. For a detailed characterization of etch selectivity, the inventors have grown samples with AlₓGa₁₋ₓN etch stop layers of various Al compositions (e.g., x=15%, 30%, and 51%) by MBE on a freestanding GaN substrate. The target thicknesses of AlₓGa₁₋ₓN layers were 60 nm, 30 nm, and 10 nm, respectively. Because of the lattice mismatch, there is an inverse relationship between the percentage of Al and achievable etch-stop thickness. In particular, N-face GaN is grown to mimic the thinning process of [Ref. 1]; the GaN template obtained by the LLO process is N-face. FIG. 1(b) shows the cross section of one sample with an Al_{0.30}Ga_{0.70}N layer that is about 25 nm thick.

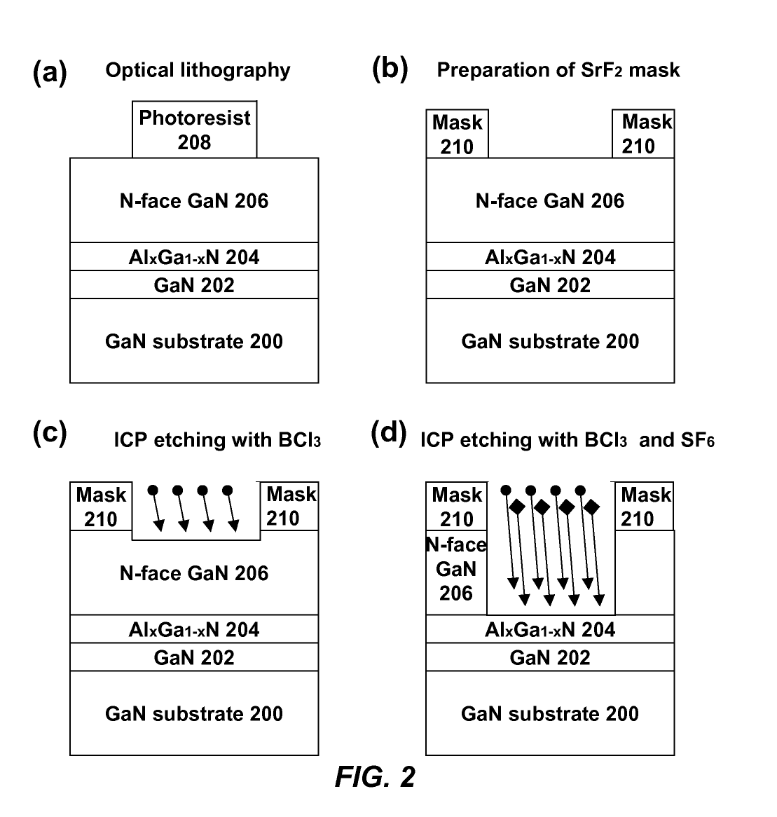

The experimental procedure is illustrated in FIGS. 2(a)-2(d) and described as follows:

(1) Growth on a GaN substrate 200, including a GaN layer 202, an AlₓGa₁₋ₓN layer 204 and an N-face GaN layer 206, followed by patterning photoresist mesas 208 on the N-face GaN 206 using optical lithography, as shown in FIG. 2(a).

(2) Introducing a 200 nm-thick SrF₂ mask layer 210 by e-beam deposition and a lift-off technique to remove the photoresist 208, as shown in FIG. 2(b).

(3) Pre-cleaning of the exposed N-face GaN 206 with BCl₃ based dry etching using an ICP etching system (Panasonic ICP Model E640), as shown in FIG. 2(c).

(4) Selective removal of the exposed N-face GaN 206 using BCl₃ and SF₆ based ICP etching, as shown in FIG. 2(d).

(5) Inspection of the etch rate and etch damage on the surface by scanning electron microscopy (SEM) and atomic force microscopy (AFM).

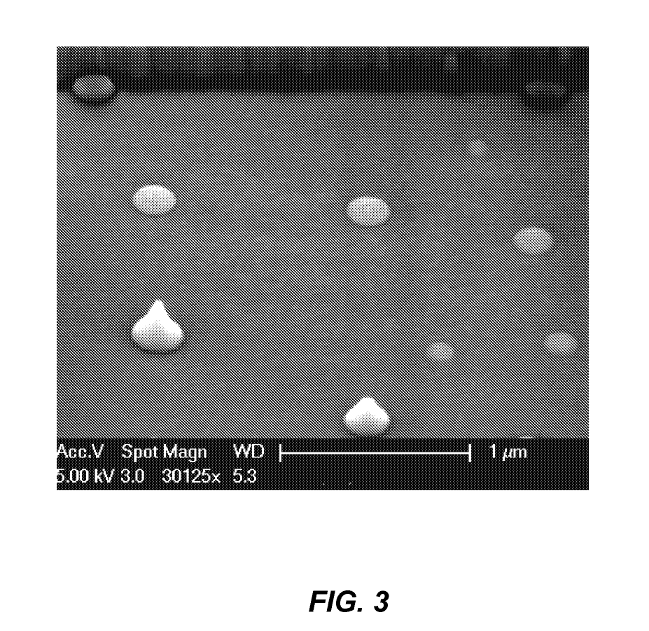

FIG. 3 is a SEM image of the etch surface after the 15 min ICP etching. As the etch gases, 20 sccm BCl₃ and 5 sccm SF₆ were used. The chamber pressure was 5 Pa. The source and bias powers were 250 W and 60 W, respectively. The low bias power is used to minimize the sputter-removal of the otherwise non-volatile AlF₃ formed at the surface, which retards further etching of the AlGaN layer. The etch surface is characterized by a flat region (the Al_{0.30}Ga_{0.70}N etch stop layer) and some submicron-sized cones and dots.

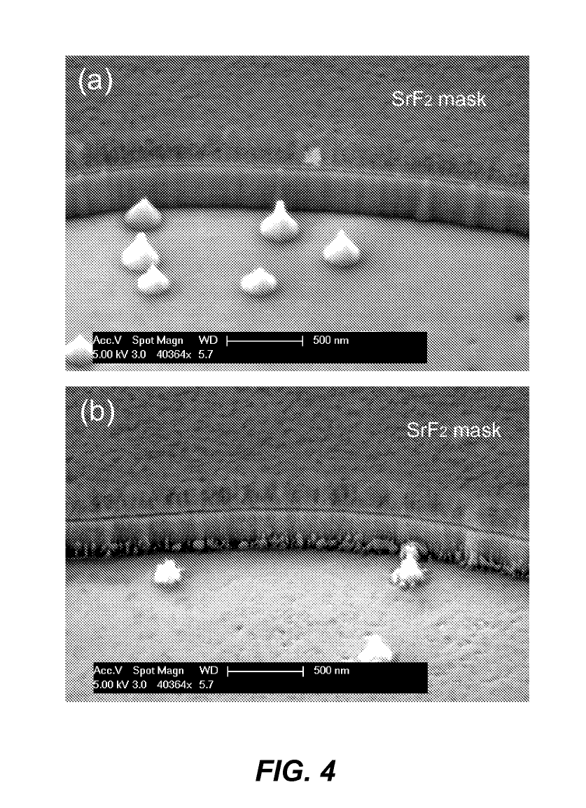

To investigate the etch damage on the Al_{0.30}Ga_{0.70}N surface, the inventors carried out an extended 20 minutes of ICP etching for another sample at the same ICP condition. The surface quality of the Al_{0.30}Ga_{0.70}N etch stop layer seems to be similar to that from 15 minutes of ICP etching, as shown in FIG. 4(a). An additional 20 minutes (for a total of 40 minutes) of ICP etching resulted in some sputter removal of the surface, as shown in FIG. 4(b). In both cases, the etch depth is almost the same as that of the 15 minutes of ICP etching. This suggests an etch selectivity of at least 14 to 1 between N-face GaN and Al_{0.30}Ga_{0.70}N.

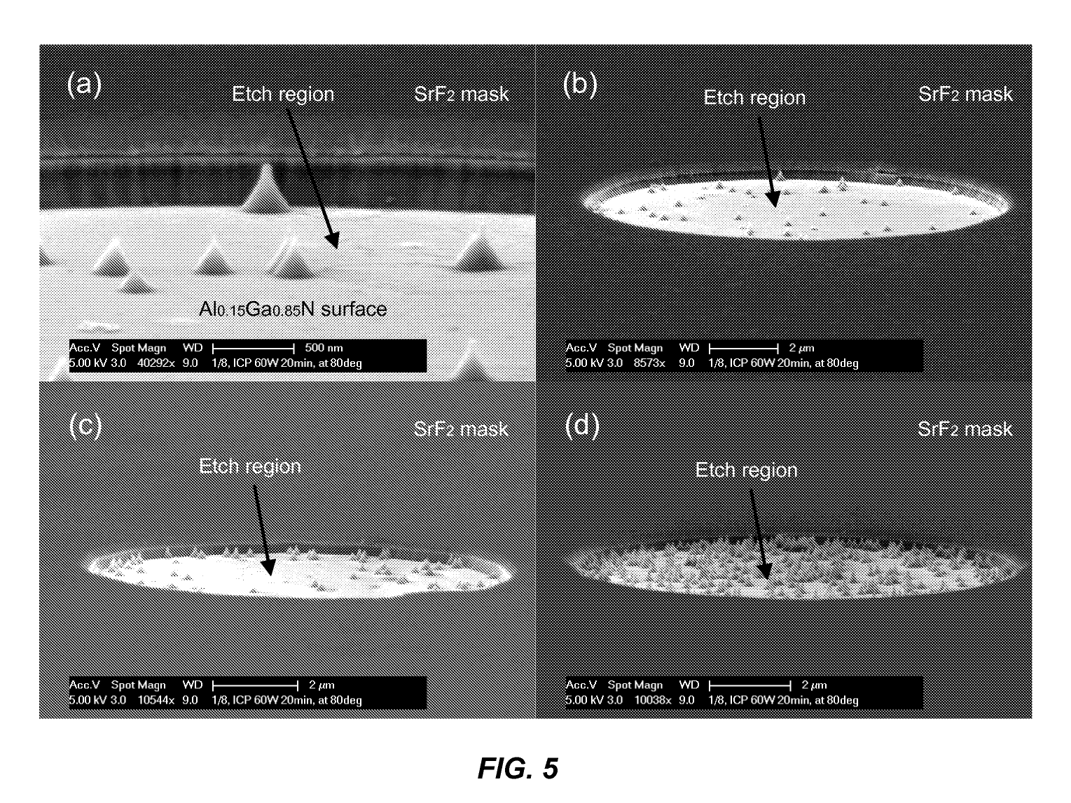

The correlation between the etch selectivity and the sample structure, i.e., the Al composition (x) in the AlₓGa₁₋ₓN layer, was also investigated by the inventors. FIGS. 5(a) and 5(b) are SEM images that show the etch results of a sample with a 60 nm thick Al_{0.15}Ga_{0.85}N layer. FIGS. 5(c) and 5(d) are SEM images that show the etch results of samples with 30 nm thick Al_{0.30}Ga_{0.70}N and 10 nm thick Al_{0.51}Ga_{0.49}N layers. The thickness of the N-face GaN was 260 nm for all samples with different AlₓGa₁₋ₓN etch stop layers. The samples were processed at the same ICP conditions concurrently.

All the AlₓGa₁₋ₓN layers demonstrate very robust etch-stopping behavior, as shown in FIGS. 5(a)-5(d). Interestingly, it appears that there is a correlation between the number of submicron-sized cones and the Al composition (x). In the inventors' test samples, the N-face GaN layer was grown on the AlₓGa₁₋ₓN etch stop layer. A larger lattice mismatch from a higher Al composition would result in a GaN layer with poorer material quality such as pits or threading dislocation, and a subsequent formation of submicron-sized cones.

### EMBODIMENTS OF THE INVENTION

Embodiments of the present invention may involve the fabrication of MCLEDs or PC-MCLEDs. The fabrication procedures for the epi-structures grown on two types of substrates, i.e., Sapphire and GaN, are described below.

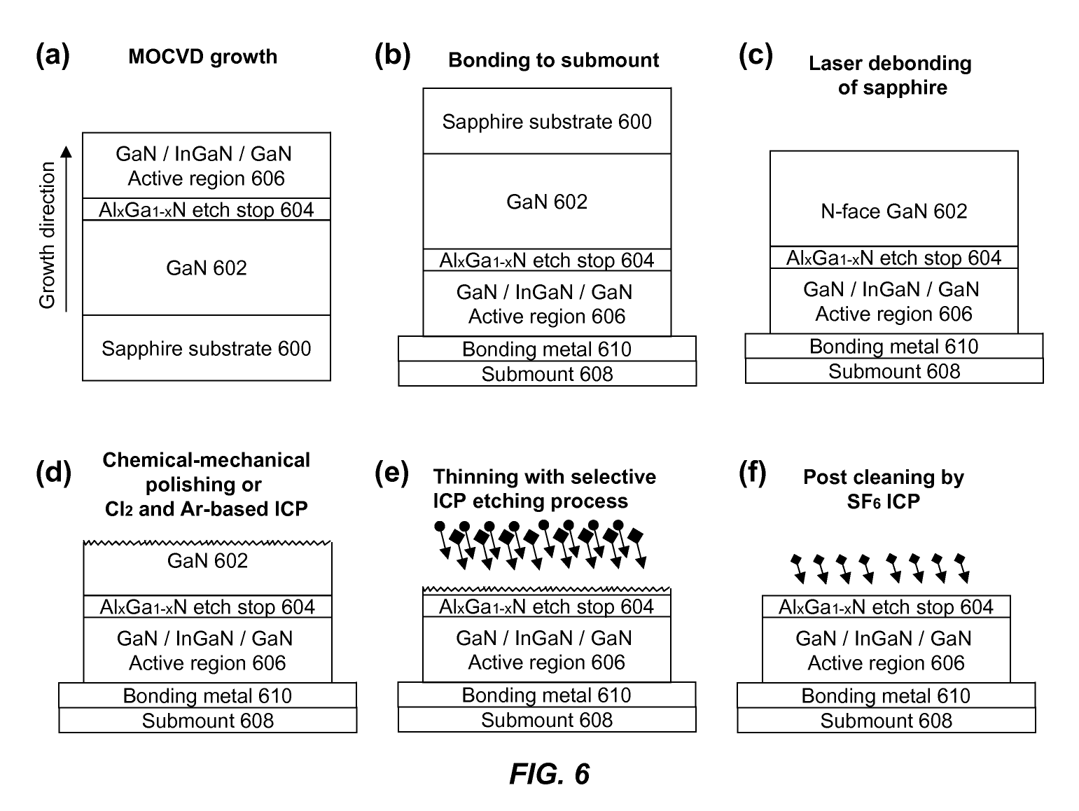

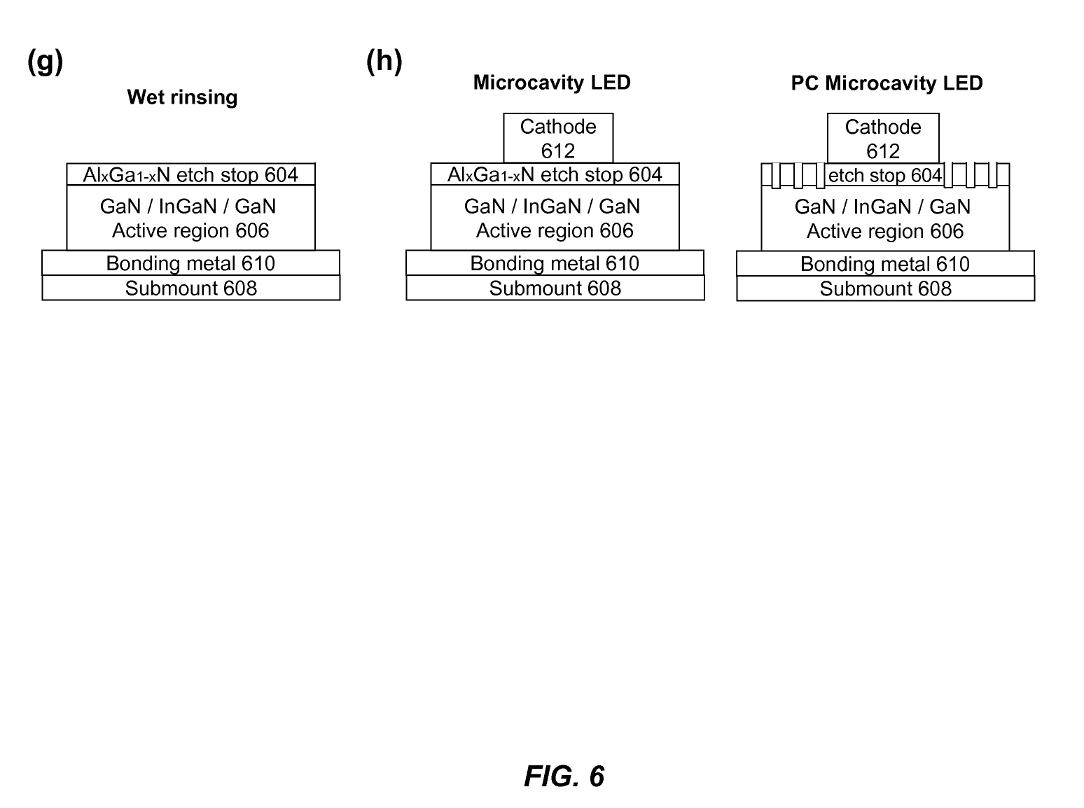

FIGS. 6(a)-6(h) are simplified schematic diagrams showing the steps of a process, according to one embodiment of the present invention, used to fabricate MCLEDs and/or PC-MCLEDs for an epi-structure grown on a Sapphire substrate 600. The steps of this first fabrication procedure are described as follows:

(1) Growth of the epi-structure with a GaN layer 602, an AlₓGa₁₋ₓN etch stop layer 604 and a GaN/InGaN/GaN active region 606 on the Sapphire substrate 600 by metalorganic chemical vapor deposition (MOCVD), as shown in FIG. 6(a).

(2) Metal wafer bonding to a submount 608 using bonding metals 610 such as Tin (Sn) and Gold (Au), as shown in FIG. 6(b).

(3) Laser debonding of the Sapphire substrate 600, as shown in FIG. 6(c).

(4) Initial thinning process utilizing a chemical mechanical polishing or non-selective (Cl and Ar-based) dry-etch process with the ICP system (Panasonic ICP Model E640), as shown in FIG. 6(d).

(5) Pre-cleaning of the N-face GaN 602 surface with BCl₃ based dry etching with the ICP system (not shown).

(6) Selective thinning of the N-face GaN 602 with BCl₃ and SF₆-based ICP etching, as shown in FIG. 6(e).

(7) Post-cleaning of GaN microcones on the surface of AlₓGa₁₋ₓN layer 604 with SF₆ based ICP etching, as shown in FIG. 6(f).

(8) Rinse with HCl, de-ionized water, acetone, and isopropanol, as shown in FIG. 6(g).

(9) Cathode 612 deposition to form an MCLED, as shown in FIG. 6(h), or

(10) Photonic-crystal (PC) formation in the etch stop layer 604 and cathode 612 deposition to form a PC-MCLED, also as shown in FIG. 6(h).

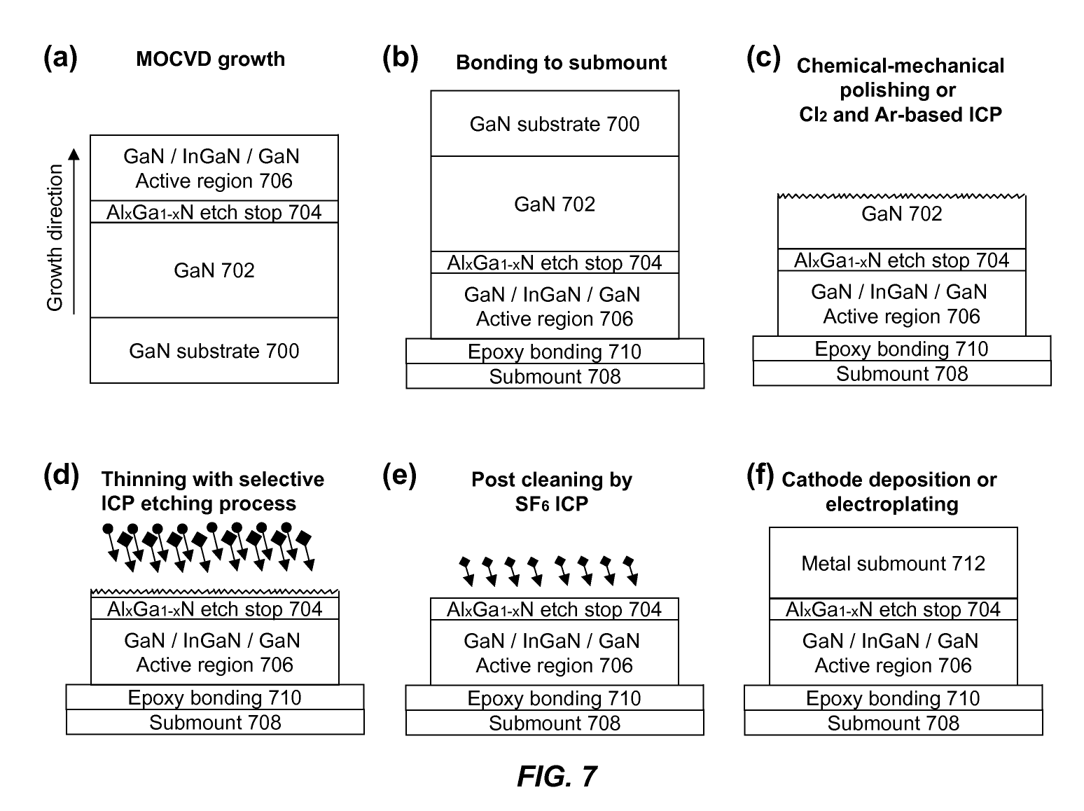

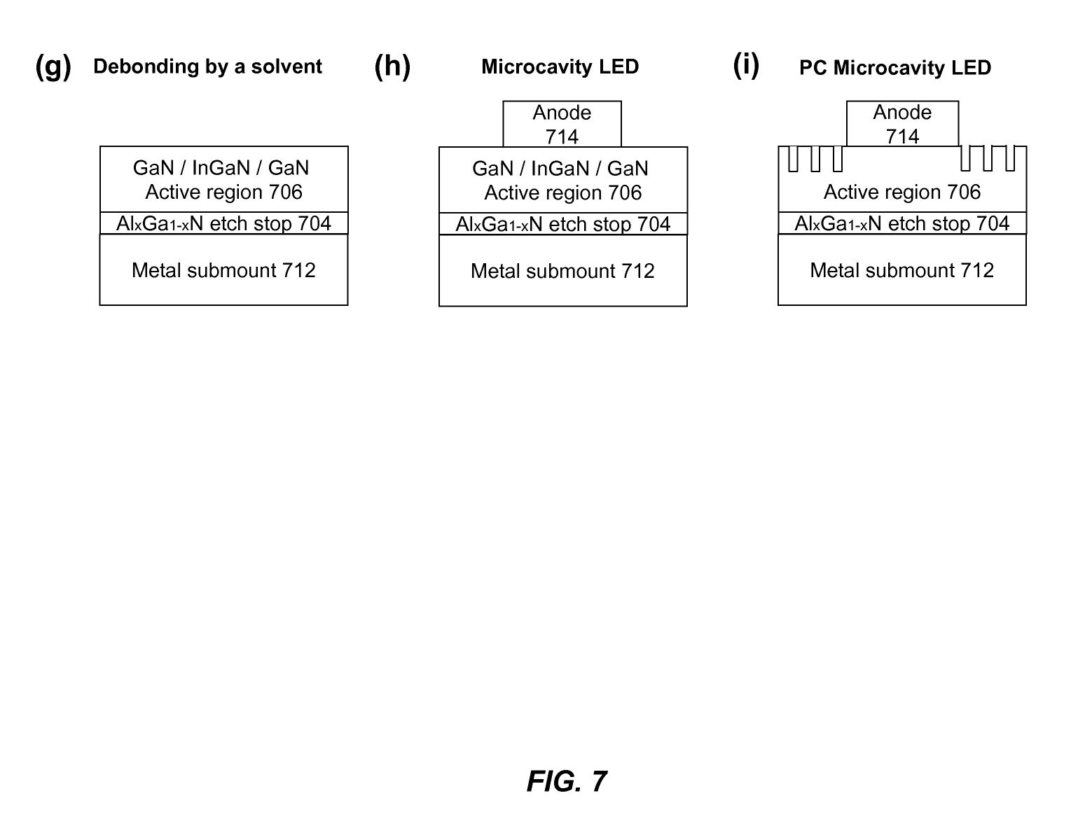

FIGS. 7(a)-7(h) are simplified schematic diagrams showing the steps of a process, according to one embodiment of the present invention, used to fabricate MCLEDs and/or PC-MCLEDs for an epi-structure grown on a free-standing GaN substrate 700. The steps of this second fabrication procedure are described as follows:

(1) Growth of the epi-structure with a GaN layer 702, an AlₓGa₁₋ₓN etch stop layer 704 and a GaN/InGaN/GaN active region 706 on the GaN substrate 700 by MOCVD, as shown in FIG. 7(a).

(2) Wafer bonding to a temporary glass submount 708 using an epoxy glue 710, which is soluble by acetone, as shown in FIG. 7(b).

(3) An initial thinning process utilizing a chemical mechanical polishing or non-selective (Cl and Ar-based) dry-etch process with the ICP system (Panasonic ICP Model E640), as shown in FIG. 7(c).

(4) Pre-cleaning of the N-face GaN 702 surface with BCl₃ based dry etching with the ICP system (not shown).

(5) Selective thinning of the N-face GaN 702 with BCl₃ and SF₆-based ICP etching, as shown in FIG. 7(d).

(6) Post-cleaning of GaN microcones on the surface of the AlₓIn₁₋ₓN etch stop layer 704 with a SF₆ based ICP etching, as shown in FIG. 7(e).

(7) Rinse with HCl, de-ionized water (not shown).

(8) Introducing a thick metal submount 712, which serves as a cathode and a mirror, by electron-beam deposition or electroplating, as shown in FIG. 7(f).

(9) Debonding the sample from the submount 708 using a solvent, such as acetone, as shown in FIG. 7(g).

(10) Anode 714 deposition, such as a transparent Pd/Au metal or indium-tin-oxide (ITO) contact, to form an MCLED, as shown in FIG. 7(h), or

(11) Photonic crystal formation in the active region 706 and anode 714 deposition, such as a transparent Pd/Au metal or indium-tin-oxide (ITO) contact, to form a PC-MCLED, also as shown in FIG. 7(i).

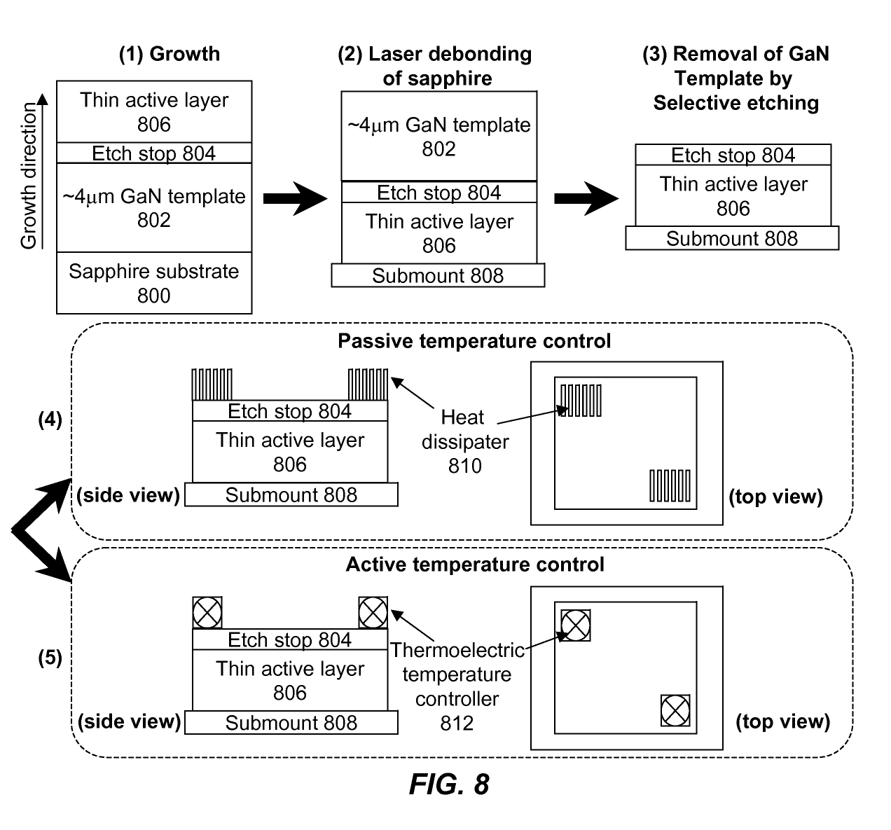

Another embodiment is the fabrication of a thin nitride-based film for efficient thermal management combined with a submount made of good thermal conductors. This can be integrated with a passive temperature control unit (e.g., heat dissipater) as well as an active temperature control unit (e.g., thermoelectric temperature controller), as shown in FIG. 8. Specifically, FIG. 8 are simplified schematic diagrams showing the steps of a process, according to one embodiment of the present invention, used to fabricate a thin Group-III nitride-based film for efficient thermal management with a passive temperature control unit (heat dissipater) or an active temperature control unit (thermoelectric temperature controller). The steps of this fabrication procedure include: (1) growth on a Sapphire substrate 800 of a ˜4 μm GaN template 802, an AlGaN etch stop layer 804, and a thin active layer 806, (2) bonding of a submount 808 and laser debonding of the Sapphire substrate 800, (3) removal of the GaN template 802 by selective etching, and finally, the fabrication of (4) a passive temperature control comprising a heat dissipater 810 (shown in both side and top views) or (5) an active temperature control comprising a thermoelectric temperature controller 812 (shown in both side and top views). These structures may comprise a device (e.g., MCLEDs or PC-MCLEDs), as well as a template for overgrowth or vertical integration of other device structures.

Other embodiments would include nitride semiconductor lasers as well as electronic devices that require the etch selectivity between N-face nitride layers and an AlₓIn₁₋ₓN etch stop layer.

Some examples of the many products that would benefit from the present invention include III-nitride-based MCLEDs, PC-MCLEDs, and High-Electron Mobility Transistors (HEMTs).

Other are areas that would benefit from the present invention include:

(1) Optimization of MOCVD growth for (Al,In,Ga)N heterostructures with a thin (400 nm) AlₓGa₁₋ₓN etch stop layer where 0.1<x<0.5.

(2) Optimization of Hydride Vapor Phase Epitaxy (HVPE) growth for (Al,In,Ga)N heterostructures with a thin (400 nm) AlₓGa₁₋ₓN etch stop layer where 0.1<x<0.5.

(3) Optimization of ICP conditions to maximize etch selectivity between (Al,In,Ga)N heterostructures.

(4) Optimization of ICP conditions to minimize etch damage to a (Al,In,Ga)N hetero structures.

(5) Optimization of ICP conditions to minimize the roughness of the etch surface. Nomenclature

The terms “(Al,In,Ga)N”, “III-nitride”, “Group-III nitride”, or “nitride,” or GaN, AlGaN, InGaN or AlInGaN, as used herein refer to any alloy composition of the (Al,In,Ga)N semiconductors having the formula AlₓIn_{y}Ga_{z}N where 0≦x≦1, 0≦y≦1, 0≦z≦1, and x+y+z=1. These terms are intended to be broadly construed to include respective nitrides of the single species, Al, In and Ga, as well as binary, ternary and quaternary compositions of such Group III metal species. Accordingly, it will be appreciated that the discussion of the invention hereinafter in reference to GaN, AlGaN and InGaN materials is applicable to the formation of various other (Al,In,Ga)N material species. Further, (Al,In,Ga)N materials within the scope of the invention may further include minor quantities of dopants and/or other impurity or inclusional materials.

### REFERENCES

The following references are incorporated by reference herein:
1. T. Fujii, A. David, C. Schwach, P. M. Pattison, R. Sharma, K. Fujito, T. Margalith, S. P. DenBaars, C. Weisbuch, and S. Nakamura, “Micro cavity effect in GaN-based light-emitting diodes formed by laser lift-off and etch-back technique,” Japanese Journal of Applied Physics, vol. 43, pp. L411-L413, 2004.
2. A. David, T. Fujii, B. Moran, S. Nakamura, S. P. DenBaars, and C. Weisbuch, “Photonic crystal laser lift-off GaN light-emitting diodes,” Applied Physics Letters, vol. 88, 133514, 2006.
3. E. F. Schubert, N. E. J. Hunt, M. Micovic, R. J. Malik, D. L. Sivco, A. Y. Cho, and G. J. Zydzik, “Highly efficient light-emitting diodes with microcavities,” Science, vol. 265, pp. 943-945, 1994.
4. N. E. J. Hunt, E. F. Schubert, R. A. Logan, G. J. Zydzik, “Enhanced spectral power density and reduced linewidth at 1.3 μm in an InGaAsP quantum well resonant-cavity light-emitting diode,” Applied Physics Letters, vol. 61, pp. 2287-2289, 1992.
5. C. Dill, R. P. Stanley, U. Oesterle, D. Ochoa, and M. Ilegems, “Effect of detuning on the angular emission pattern of high-efficiency Microcavity light-emitting diodes,” Applied Physics Letters, vol. 73, pp. 3812-3814, 1998.
6. H. De Neve, J. Blondelle, P. Van Daele, P. Demeester, R. Baets, and G. Borghs, “Recycling of guided mode light emission in planar Microcavity light emitting diodes,” Applied Physics Letters, vol. 70, pp. 799-801, 1997.
7. E. Feltin, J.-F. Carlin, J. Dorsaz, G. Christmann, R. Butte, M. Laugt, M. Ilegems, and N. Grandjean, “Crack-free highly reflective AlInN/AlGaN Bragg mirrors for UV applications”, Applied Physics Letters, vol. 88, pp. 051108, 2006.
8. N. Nakada, H. Ishikawa, T. Egawa, and T. Jimbo, “Suppression of crack generation in GaN/AlGaN distributed Bragg reflector on Sapphire by the insertion of GaN/AlGaN superlattice grown by metal-organic chemical vapor deposition,” Japanese Journal of Applied Physics, vol. 42, pp. L144-L146, 2003.
9. W. S. Wong, T. Sands, and N. W. Cheung, “Damage-free separation of GaN thin films from Sapphire substrates,” Applied Physics Letters, vol. 72, pp. 599-601, 1998.
10. W. S. Wong, T. Sands, N. W. Cheung, M. Kneissl, D. P. Bour, P. Mei, L. T. Romano, and N. M. Johnson, “InGaN light emitting diodes on Si substrates fabricated by Pd—In metal bonding and laser lift-off,” Applied Physics Letters, vol. 77, pp. 2822-2824, 2000.
11. Y. K. Song, M. Diagne, H. Zhou, A. V. Nurmikko, R. P. Schneider Jr., and T. Takeuchi, “Resonant-cavity InGaN quantum-well blue light-emitting diodes,” Applied Physics Letters vol. 77, pp. 1744-1746, 2000.
12. P. R. Tavernier and D. R. Clarke, “Mechanics of laser-assisted debonding of films,” Journal of Applied Physics, vol. 89, pp. 1527-1536, 2001.
13. S. R. Lee, D. D. Koleske, K. C. Cross, J. A. Floro, K. E. Waldrip, A. T. Wise, and S. Mahajan, “In situ measurements of the critical thickness for strain relaxation in AlGaN/GaN heterostructures,” Applied Physics Letters, vol. 85, pp. 6164-6166, 2004.
14. S. A. Smith, C. A. Wolden, M. D. Bremser, A. D. Hanser, R. F. Davis, and W. V. Lampert, “High rate and selective etching of GaN, AlGaN, and AN using an inductively coupled plasma,” Applied Physics Letters, vol. 71, pp. 3631-3633, 1997.
15. S. J. Pearton, J. C. Zolper, R. J. Shul, and F. Ren, “GaN: Processing, defects, and devices,” Journal of Applied Physics, vol. 86, pp. 1-78, 1999.
16. A. R. Stonas, P. Kozodoy, H. Marchand, P. Fini, S. P. DenBaars, U. K. Mishra, and E. L. Hu, “Backside-illuminated photoelectrochemical etching for the fabrication of deeply undercut GaN structures,” Applied Physics Letter, vol. 77, pp. 2610-2612, 2000.
17. D. Li, M. Sumiya, S. Fuke, D. Yang, D. Que, Y. Suzuki, and Y. Fukuda, “Selective etching of GaN polar surface in potassium hydroxide solution studied by x-ray photoelectron spectroscopy,” Journal of Applied Physics, vol. 90, pp. 4219-4223, 2001.
18. T. Fujii, Y. Gao, R. Sharma, E. L. Hu, S. P. DenBaars, and S, Nakamura, “Increase in the extraction efficiency of GaN-based light-emitting diodes via surface roughening,” Applied Physics Letters, vol. 84, pp. 855-7, 2004.
19.1. Waki, M. Iza, J. S. Speck, S. P. DenBaars, and S, Nakamura, “Etching of Ga-face and N-face GaN by Inductively Coupled Plasma,” Japanese Journal of Applied Physics, vol. 45, pp. 720-723, 2006.

### CONCLUSION

This concludes the description of the preferred embodiments of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method for dry etch selectivity in fabricating an opto-electronic device, comprising:
etching one or more nitride layers having an (Al,In,Ga)N etch-stop layer containing at least some Aluminum (Al), wherein the nitride layers are etched at a higher rate than the etch-stop layer.

2. The method of claim 1, wherein the etching is performed on an etch surface that is a (0001) (-c) Nitrogen-face (N-face) of the nitride layers.

3. The method of claim 2, wherein the nitride layers comprise one or more c-plane GaN layers and the etch surface is an as-grown (0001) (-c) N-face of the c-plane GaN layers.

5. The method of claim 1, wherein the etch-stop layer comprises an AlₓGa₁₋ₓN layer with x>0.

6. The method of claim 5, wherein the etch-stop layer comprises AlₓGa₁₋ₓN layers with 0.1<x<0.5.

7. The method of claim 1, wherein the etch-stop layer has a thickness that is greater than 1 nm.

8. The method of claim 7, wherein the etch-stop layer has a thickness that is between 10 nm and 100 nm.

9. The method of claim 1, wherein the nitride layers and etch-stop layer comprise layers of dissimilar (Al,Ga,In)N composition.

10. The method of claim 1, wherein the nitride layers and etch-stop layer comprise layers having varying or graded compositions.

11. The method of claim 1, wherein the nitride layers are etched by Inductively Coupled Plasma (ICP) etching using etch gases of SF₆, BCl₃, Cl₂, Ar, or O₂ at a source power P_{S} and bias power P_{B}, where 0<P_{S}<200 W, O<P_{B}<100 W and P_{B}<P_{S}.

12. The method of claim 11, wherein the ICP etching is carried out along with an initial chemical mechanical polishing or Reactive Ion Etching (RIE) using etch gases of SF₆, BCl₃, Cl₂, Ar, or O₂.

13. A device fabricated using the method of claim 1.

14. The of claim 13, wherein the device includes a microcavity that contains an active emitting layer.

15. A template for efficient thermal management fabricated using the method of claim 1.

16. A method for dry etch selectivity, comprising:
etching one or more nitride layers having an (Al,In,Ga)N etch-stop layer containing at least some Indium (In), wherein the nitride layers are etched at a higher rate than the etch-stop layer.

17. The method of claim 16, wherein the etch-stop layer is used as an etch stop over a Gallium face (Ga-face) or a Nitrogen face (N-face) of the nitride layers.

18. The method of claim 16, wherein an etch product InCl₃ provides a dry etch selectivity for a chlorine-based etch gas.

19. The method of claim 16, wherein an etch product InF₃ provides a dry etch selectivity for a fluorine-based etch gas.

20. A device fabricated using the method of claim 16.
